(19) United States
(12) Patent Application Publication
(10) Pub. No.: US 2010/0171415 A1
(43) Pub. Date: Jul. 8, 2010

(54) LIGHT-EMITTING DEVICE AND DISPLAY APPARATUS

(75) Inventors: Kaori AKAMATSU, Osaka (JP); Hidehiro YOSHIDA, Osaka (JP)

Correspondence Address: GREENBLUM & BERNSTEIN, P.L.C., 1950 ROLAND CLARKE PLACE, RESTON, VA, 20191, US

(73) Assignee: Panasonic Corporation, Osaka (JP)

(21) Appl. No.: 12/616,878

(22) Filed: Nov. 12, 2009

(30) Foreign Application Priority Data
Nov. 13, 2008 (JP) 2008-290934

(51) Int. Cl. H01L 51/54

(52) U.S. Cl. 313/504

(57) ABSTRACT

A light-emitting device includes a first electrode, a second electrode, a light-emitting layer between the first electrode and the second electrode, and banks that delimit the light-emitting layer. An upper surface of the light-emitting layer has a pair of sloping portions that each slope upward toward a lateral surface of one of the banks. The light-emitting layer is thicker about a lower boundary position than at a center of the light-emitting layer. The boundary position corresponds to an intersection of a lower surface of the light-emitting layer and the lateral surface of one of the banks. A width of each sloping portion is at least approximately 2 μm and at most approximately 10% of a width of the light-emitting layer. Thus, it is possible to obtain a light-emitting device having a long life and having less variation in the luminance and an organic EL display apparatus having such a light-emitting device.

This application is based on application No. 2008-290934 filed in Japan, the contents of which are hereby incorporated by reference.

### BACKGROUND OF THE INVENTION

(1) Field of the Invention

The present invention relates to a light-emitting device and a display apparatus, and particularly to an organic electro-luminescence (EL) device and an organic EL display apparatus used for a flat display and the like.

(2) Description of the Related Art

There has hitherto been an organic EL device having an organic light-emitting layer delimited by banks to define a pixel. It is desirable that the organic light-emitting layer uniformly emits light from the whole pixel, from the center to the periphery of the pixel. This is because if some portions of the organic light-emitting layer emit a large amount of light, only such portions are deteriorated earlier. This results in reduction of the life of the organic EL device, and also causes variation in the luminance of the organic EL device.

As a method to make the organic light-emitting layer in the whole pixel uniformly emit light, an organic light-emitting layer with a uniform thickness has been proposed. Patent Citation 1 (Japanese Unexamined Patent Application Publication No. 2007-61674) discloses a technique relating to process development for making the organic light-emitting layer have the uniform thickness.

Furthermore, Patent Citations 2 and 3 (Japanese Unexamined Patent Application Publication No. 2005-93421, International Publication No. 2007-113935) each disclose a technique to increase the layer thickness of the organic light-emitting layer at the periphery thereof so as to prevent the occurrence of the leaked electricity caused by the thinness of the organic light-emitting layer at the periphery.

However, the inventor has discovered a phenomenon in which if the organic light-emitting layer has the uniform thickness, a larger amount of light is emitted from the periphery of a pixel than the center. Through an analysis, the inventor has found that electric field concentration and current concentration occurred in the vicinity of the periphery of a pixel cause this phenomenon.

FIG. 12 shows a position in a conventional organic EL device where the electric field concentration and the current concentration occur. As shown in FIG. 12, according to the conventional organic EL device having a first electrode 104, an organic light-emitting layer 107, and a second electrode 110 layered in the stated order, at least the organic light-emitting layer 107 being delimited by banks 109 to define a pixel, the electric field concentration and the current concentration occur at a boundary position P1 that is located at a border between a lower surface 107a of the organic light-emitting layer 107 and a lateral surface 109a of a corresponding one of the banks 109. The reason for the occurrence of such electric field concentration is that a fringing field between the first electrode 104 and the second electrode 110 is applied to the organic light-emitting layer 107 from the lateral surface 109a of the corresponding one of the banks 109. The current concentration occurs, because the fringing field increases a current value and because the sloping shape of the corresponding one of the banks 109 causes current supplied from the second electrode 110 to be collected at P1. The electric field intensity and the current density in a portion of the light-emitting layer determine an amount of light emitted from the portion. Accordingly, if the electric field concentration and the current concentration occur at the boundary position P1, which in the vicinity of the periphery of the pixel, more light is emitted from the periphery of the pixel.

Thus, the decrease in values of the electric field intensity and the current intensity only in view of the electric field intensity and the current intensity at the periphery of the pixel serves little purpose to prevent the increase in the amount of light emitted from the periphery of the pixel. In order to prevent the increase in the light emission amount, it is important to consider the electric field intensity and the current intensity at the periphery of the pixel in terms of the relation with those at the center of the pixel. Accordingly, simply making the organic light-emitting layer thicker at the periphery thereof than at the center may not prevent the increase.

With regard to the above problem, the aforementioned Patent Citations 2 and 3 each merely disclose that the organic light-emitting layer is thicker at the periphery than at the center. Neither of Patent Citations 2 and 3 discloses anything with regard to the electric field intensity and the current intensity at the periphery of the pixel studied in relation with those at the center of the pixel.

### SUMMARY OF THE INVENTION

The present invention is conceived in view of the above problems. The object of the present invention is to provide a light-emitting device having a long life and causing little variation in the luminance.

In one aspect, the present invention provides a light-emitting device including a first electrode, a light-emitting layer, and a second electrode layered in the stated order, at least the light-emitting layer being delimited by banks to define a pixel, wherein the light-emitting layer has a sloping portion whose upper surface slopes upwardly towards a periphery of the pixel such that the light-emitting layer is thicker at a boundary position P1 than at a center thereof, the boundary position P1 being located at a border between a lower surface of the light-emitting layer and a lateral surface of a corresponding one of the banks, and a width W of the sloping portion is 2 μm or more, and is 10% or less of a width of the light-emitting layer, the width W being a distance from a position at which the sloping portion starts to slope upwardly to a periphery of the light-emitting layer in a horizontal direction.

With regard to the light-emitting layer of the light-emitting device pertaining to one aspect of an embodiment of the present invention, the light-emitting layer is thicker at the boundary position P1, which is located at the border between the lower surface of the light-emitting layer and the lateral surface of the corresponding one of the banks, than at the center. Furthermore, the width W of the sloping portion is 2 μm or more and is 10% or less of the width of the light-emitting layer. As a result, compared with a conventional light-emitting layer whose thickness at the boundary position P1 shown in FIG. 12 is the same as that at the center, the electric field concentration and the current concentration are less likely to occur in the vicinity of the periphery of the light-emitting layer. Accordingly, the light-emitting device in accordance with the present invention has a longer life and has less variation in the luminance.

More specifically, since the light-emitting layer is thicker at the boundary position P1, the distance between the first electrode and the second electrode is increased at the boundary position P1. The increased distance alleviates the electric field concentration at the boundary position P1, and elongates the length of a path of the current flowing along the surface of the corresponding one of the banks. As a result, a resistance value is increased and the current concentration is alleviated.

A width W of the sloping portion is 2 μm or more, and is 10% or less of a width of the light-emitting layer, the width W being a distance from a position at which the sloping portion starts to slope upwardly to a periphery of the light-emitting layer in a horizontal direction. Accordingly, as described later, this prevents the occurrence of the electric field concentration and the current concentration at the periphery of the light-emitting layer.

This results in the reduction in an amount of light emitted from the light-emitting layer at the boundary position P1 and the decrease in a difference in the amount of light emission between at the boundary position P1 and other portions, thereby suppressing the variation in the amount of light emitted from the whole pixel. Thus, it can be expected to dissolve the deterioration of some portions of the light-emitting layer and the variation in the luminance.

### BRIEF DESCRIPTION OF THE DRAWINGS

These and the other objects, advantages and features of the invention will become apparent from the following description thereof taken in conjunction with the accompanying drawings which illustrate a specific embodiment of the invention.

In the drawings:

FIG. 1 is a perspective view of a display apparatus and so on pertaining to one aspect of an embodiment of the present invention;

FIG. 2 is a schematic view showing a state where layers of a light-emitting device pertaining to one aspect of the embodiment of the present invention are layered with one another;

FIG. 3 is a schematic view of the main structure of the light-emitting device pertaining to one aspect of the embodiment of the present invention;

FIG. 4 is a sectional view of the light-emitting device taken along the line A-A shown in FIG. 2;

FIG. 5A shows a relation between a bank angle α and electric field concentration; and FIG. 5B shows a relation between the bank angle α and current concentration;

FIG. 6A shows a relation between a width W of a protruding portion and the electric field concentration when the protruding portion is 20 nm high; and FIG. 6B shows a relation between the width W of the protruding portion and the current concentration;

FIG. 7A shows a relation between the width W of the protruding portion and the electric field concentration when the protruding portion is 50 nm high; and FIG. 7B shows a relation between the width W of the protruding portion and the current concentration;

FIG. 8A shows a relation between the width W of the protruding portion and the electric field concentration when the protruding portion is 90 nm high; and FIG. 8B shows a relation between the width W of the protruding portion and the current concentration;

FIG. 9A shows a relation between the height H of the protruding portion and the electric field concentration; and

FIG. 9B shows a relation between the height H of the protruding portion and the current concentration;

FIG. 10 is a schematic view of the main structure of a light-emitting device pertaining to Modification 1;

FIG. 11 is a schematic view of the main structure of a light-emitting device pertaining to Modification 2; and

FIG. 12 shows a position where electric field concentration and current concentration occur in a conventional organic EL device.

### DESCRIPTION OF THE PREFERRED EMBODIMENT

A light-emitting device pertaining to one aspect of an embodiment of the present invention includes a first electrode, a light-emitting layer, and a second electrode layered in the stated order, and at least the light-emitting layer is delimited by banks to define a pixel. The light-emitting layer has a sloping portion whose upper surface slopes upwardly towards a periphery of the pixel such that the light-emitting layer is thicker at a boundary position P1 than at a center thereof. The boundary position P1 is located at a border between a lower surface of the light-emitting layer and a lateral surface of a corresponding one of the banks, and a width W of the sloping portion is 2 μm or more, and is 10% or less of a width of the light-emitting layer, the width W being a distance from a position at which the sloping portion starts to slope upwardly to a periphery of the light-emitting layer in a horizontal direction.

In accordance with the light-emitting device pertaining to one aspect of the embodiment of the present invention, a boundary position P2 may be higher than the upper surface of the light-emitting layer at the center by 20 nm or more. The boundary position P2 is located at a border between the upper surface of the light-emitting layer and the lateral surface of the corresponding one of the banks.

In accordance with the light-emitting device pertaining to one aspect of the embodiment of the present invention, the width W of the sloping portion may fall within a range between 5 μm and 10 μm, inclusive and the boundary position P2 may be higher than the upper surface of the light-emitting layer at the center by 50 nm to 100 nm, inclusive.

In accordance with the light-emitting device pertaining to one aspect of the embodiment of the present invention, an angle α formed between the lateral surface and a lower surface of the corresponding one of the banks may be an acute angle.

In accordance with the light-emitting device pertaining to one aspect of the embodiment of the present invention, the banks may surround a periphery of the light-emitting layer.

In accordance with the light-emitting device pertaining to one aspect of the embodiment of the present invention, the banks may be disposed on two opposing sides of the light-emitting layer in a row direction or in a column direction.

In accordance with the light-emitting device pertaining to one aspect of the embodiment of the present invention, the lower surface of the corresponding one of the banks may be in contact with the first electrode, a top portion of the corresponding one of the banks may exit inside the second electrode, and the corresponding one of the banks may slope from the lower surface to the top portion.

A display apparatus pertaining to one aspect of an embodiment of the present invention may have the light-emitting device pertaining to one aspect of the embodiment of the present invention.

The following describes a light-emitting device pertaining to one aspect of an embodiment of the present invention with reference to the drawings.

### [Structure of Display Apparatus]

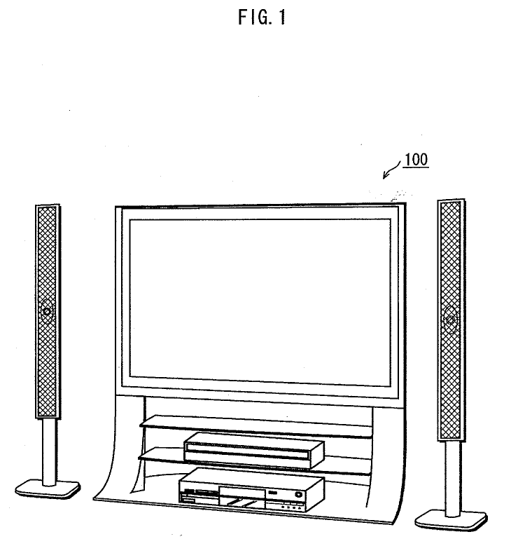

FIG. 1 is a perspective view of a display apparatus and so on pertaining to one aspect of the embodiment of the present invention. As shown in FIG. 1, a display apparatus 100 pertaining to one aspect of the embodiment of the present invention is an organic EL display having pixels that emit RGB light arranged in a matrix form in the row direction and the column direction. Each pixel is composed of the light-emitting device pertaining to one aspect of the embodiment.

### [Structure of Light-Emitting Device]

### <Overall Structure>

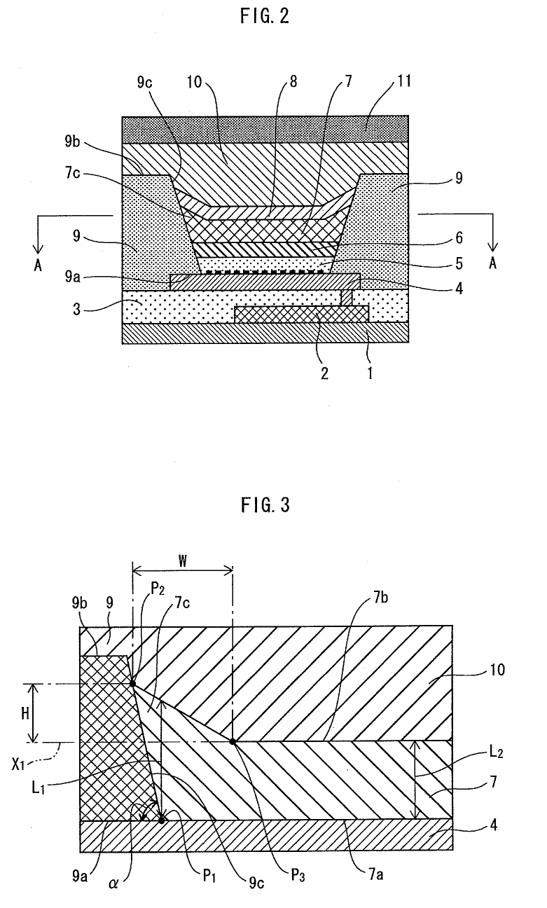

FIG. 2 is a schematic view showing where layers of the light-emitting device pertaining to one aspect of the embodiment of the present invention are layered with one another.

The light-emitting device in accordance with the embodiment is a top-emission type organic EL device. The RGB pixels each composing the light-emitting device are orderly arranged in a matrix form. As shown in FIG. 2, each pixel is layered on a TFT 2. Note that the light-emitting device pertaining to the present invention may be a bottom-emission type organic EL device. In such a case, the light-emitting device and the TFT are formed on the same planar surface.

The light-emitting device shown in FIG. 2 is disposed on a planar film 3 that covers a substrate 1 on which the TFT is disposed. More specifically, a first electrode (reflective anode) 4, which is connected to a drain electrode (unillustrated) of the TFT 2, is arranged in a matrix form on the planar film 3. Furthermore, a hole-injection layer 5 is layered on the first electrode 4, and banks 9 surround the hole-injection layer 5. Within a portion of the hole-injection layer 5 surrounded by the banks 9, an interlayer 6, a light-emitting layer (organic light-emitting layer) 7, and an electron-injection layer 8 are layered in the stated order, which forms a multilayer structure. This multilayer structure realizes a functional layer. Note that the functional layer may include a hole-transport layer and an electron-transport layer.

On the electron-injection layer 8, a second electrode (cathode) 10 and a sealing layer 11 are layered in the stated order. The lower surface 9a of each of the banks 9 is in contact with the first electrode 4, and a top portion 9b of the each of the banks 9 exists inside the second electrode 10. The banks 9 are each in a shape sloping from the lower surface 9a to the top portion 9b thereof. The hole-injection layer 5, the interlayer 6, the light-emitting layer 7 and the electron-injection layer 8 are delimited by the banks 9 so as to define a pixel. On the other hand, the second electrode 10 and the sealing layer 11 are continuous from those in the adjacent pixels across the banks 9. Note that the banks 9 may delimit the second electrode 10 and the sealing layer 11 to define a pixel. The electron-injection layer 8 may be continuous from those in the adjacent pixels across the banks 9.

### <Structure of Component>

The following more specifically describes each of the components composing the light-emitting device.

The substrate 1 is desirably made from an insulating material, such as soda glass, nonluminescent glass, phosphoric acid glass, boric acid glass, quartz, acrylic resin, styrene resin, polycarbonate resin, epoxy resin, polyethylene, polyester, silicone resin, and alumina.

When the light-emitting device is a top-emission type device, the first electrode 4 needs to be reflective to light. The first electrode 4 is, therefore, desirably made from a light-reflective material, such as APC (alloy of silver, palladium, and copper), ARA (alloy of silver, rubidium, and gold), MoCr (alloy of molybdenum and chrome), and NiCr (alloy of nickel and chrome).

In contrast, when the light-emitting device is a bottom-emission type device, the first electrode 4 needs to be transmissive to light. The first electrode 4 is, therefore, desirably made from a light-transmissive material, such as ITO (indium tin oxide), IZO (indium zinc oxide), and tin oxide. Note that when the light-emitting device is a bottom-emission type device, the substrate 1 also needs to be transmissive to light. It is, therefore, desirable that the substrate 1 is made from a light-transmissive material, such as glass, polyethylene terephtharate, and polyethylene naphtharate.

The hole-injection layer 5 enhances the efficiency of injection of holes from the first electrode 4. For example, the hole-injection layer 5 is made from an organic material, such as PEDOT-PSS (polyethylenedioxythiophene doped with polystylene sulfonic acid), poly 3,4-ethylenedioxythiophene and their derivative.

The interlayer 6 blocks electrons from being transported from the light-emitting layer 7 to the hole-injection layer 5, and effectively conveys holes to the light-emitting layer 7. The light-emitting layer 7 is desirably made from an organic material, such as triphenylamine, and polyaniline.

The light-emitting layer 7 is desirably made from a fluorescent material, such as an oxynoide compound, a perylene compound, a coumarin compound, an azacoumarin compound, an oxazole compound, an oxadiazole compound, a perinone compound, a pyrrolopyrrole compound, a naphthalene compound, an anthracene compound, a fluorene compound, a fluoranthene compound, a tetracene compound, a pyrene compound, a coronene compound, a quinolone compound and an azaquinolone compound, a pyrazoline derivative and a pyrazolone derivative, a rhodamine compound, a crysene compound, a phenanthrene compound, a cyclopentadiene compound, a stilbene compound, a diphenylquinone compound, a styryl compound, a butadiene compound, a dicyanomethylene pyran compound, a dicyanomethylene thiopyran compound, a fluorescein compound, a pyrylium compound, a thiapyrylium compound, a selenopyrylium compound, a telluropyrylium compound, an atomatic aldadiene compound, an oligophenylene compound, a thioxanthen compound, an anthracene compound, a cyanine compound, an acridine compound, a metal complex of a 8-hydroxyquinoline compound, a metal complex of a 2,2′-bipyridine compound, a complex of schiff base and III-group metal, an oxinemetal complex, a rare-earth complex, etc. as disclosed by Japanese Unexamined Patent Application Publication No. H5-163488.

The electron-injection layer 8 transports electrons injected from the second electrode 10 to the light-emitting layer 7, and is desirably made from barium, phthalocyanine, and lithium fluoride or the like, or made from a combination of these.

The banks 9 may be made from an insulating material, and desirably is resistant to an organic solvent. In addition, it is desirable that the banks 9 are transmissive to visible light to some extent. Furthermore, since the banks 9 may be etched, baked or the like, the banks 9 are desirably made from a material highly resistant to these processing. The banks 9 may be made either from an organic material, such as a resin, or an inorganic material, such as glass. The organic material is, for instance, an acrylic resin, a polyimide resin, a novolac-type phenolic resin and the like. The inorganic material is, for instance, SiO₂ (silicon oxide), Si₃N₄ (silicon nitride) and the like.

The banks 9 may be formed as a pixel bank or a line bank. The pixel bank surrounds the periphery of the light-emitting layer 7 in each pixel. On the other hand, the line bank separates a plurality of pixels in columns or rows. That is, the banks 9 are disposed on two opposing sides of the light-emitting layer 7 in the row direction or the column direction, and continuances of the light-emitting layer 7 are disposed in the pixels in the row or the column direction.

When the light-emitting device is a top-emission type device, the second electrode 10 is desirably made from a light transmissive material, such as ITO and IZO. When the light-emitting device is a bottom-emission type device, the second electrode 10 is desirably made from a light-reflective material, such as aluminum.

The sealing layer 11 prevents the light-emitting layer 7 and the like from being exposed to moisture or air. It is desirable that the sealing layer 11 is made from, for example, SiN (silicon nitride) or SiON (silicon oxynitride). In particular, when the light-emitting device is a top-emission type device, since the sealing layer 11 is disposed on the path of the light emitted from the light-emitting layer 7, the sealing layer 11 is desirably transmissive to light.

### <Structure of Light-Emitting Layer>

FIG. 3 is a schematic view of the main structure of the light-emitting device in accordance with the embodiment.

The light-emitting device in accordance with the embodiment is particularly characterized by the shape of the light-emitting layer 7. As shown in FIG. 3, in each pixel, the light-emitting layer 7 is thicker at the boundary position P₁, which is located at a border between the lower surface 7a of the light-emitting layer 7 and the lateral surface 9c of the corresponding one of the banks 9, than at the center thereof. More specifically, the upper surface 7b of the light-emitting layer 7 slopes upwardly from a position nearer the center of the pixel than the boundary position P1 towards the lateral surface 9c of the corresponding one of the banks 9. The lower surface 7a of the light-emitting layer 7 is flat across the whole pixel. Thus, according to the light-emitting layer 7, the distance L₁ between the first electrode 4 and the second electrode 10 at the boundary position P₁ (thickness of the light-emitting layer at the boundary position P₁) is longer than the distance L₂ between the first electrode 4 and the second electrode 10 at the center (the thickness of the light-emitting layer at the center). Thus, compared with a conventional layer where the distance L₁ equals to the distance L₂, the electric field concentration and the current concentration are less likely to occur at the boundary position P₁. As a result, the light-emitting layer at the boundary position P₁ emits a smaller amount of light than a conventional layer. Thus, the whole pixel has little variation in the luminance.

In addition to the light-emitting layer 7, other layers composing the functional layer are layered between the first electrode 4 and the second electrode 10. Note that it is possible to more effectively suppress the electric field concentration and the current concentration when the thickness of each layer is made substantially uniform in the whole pixel.

With regard to the light-emitting device in accordance with the embodiment, a portion with the increased thickness at the boundary position P₁ (a portion above the chain double-dashed line X₁ in FIG. 3) is referred to as a protruding portion 7c. The protruding portion 7c is a sloping portion sloping upwardly from the position towards the center of the pixel towards the lateral surface 9c of the corresponding one of the banks 9. The width W of the protruding portion 7c is a distance from the boundary position P2, which is located at a border between the upper surface 7b of the light-emitting layer 7 and the lateral surface 9c of the corresponding one of the banks 9, to a base point P3 of the protruding portion 7c (the width is measured in a direction parallel to the upper surface of the substrate 1). The height H of the protruding portion 7c is a distance from the base point P3 to the boundary position P2 (the height is measured in a direction orthogonal to the upper surface of the substrate 1).

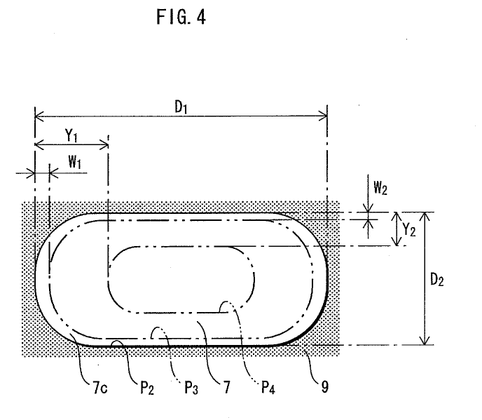

FIG. 4 is a sectional view of the light-emitting device taken along in the A-A line shown in FIG. 2. For the convenience of the description, the electron-injection layer 8 is omitted. As shown in FIG. 4, as for the pixel bank, the banks 9 surrounds the light-emitting layer 7, and the protruding portion 7c is formed in an annular shape along the banks 9. Accordingly, the boundary position P2 and the base point P3 in FIG. 3 are respectively shown as P2 and P3 located on the chain double-dashed line defined by the reference numerals P2 and P3 in FIG. 4.

A central portion of the pixel which is in the vicinity of the center of the light-emitting layer according to the present invention is a portion surrounded by the chain double-dashed line shown by reference numeral P4 in FIG. 4. The distance from the corresponding one of the banks 9 to the chain double-dashed line shown by the reference numeral P4 is 25% of the width of the upper surface 7b of the light-emitting layer 7 (the distance Y1 is 25% of the width D1, the distance Y2 is 25% of the width D2).

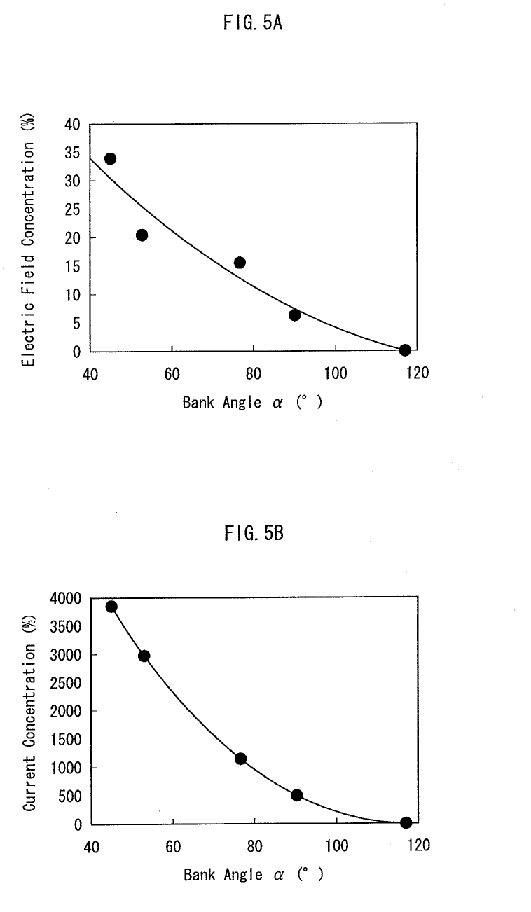

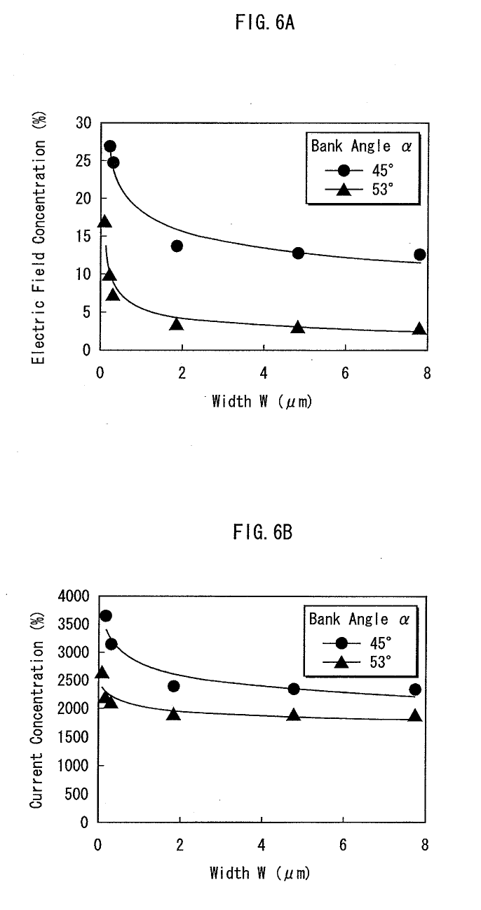

FIG. 5A shows a relation between a bank angle α and the electric field concentration. FIG. 5B shows a relation between the bank angle α and the current concentration. FIGS. 5A and 5B each indicate, in the X axis, the bank angle α formed by the lower surface 9a and the lateral surface 9c of the corresponding of the banks 9 (see FIG. 3). FIG. 5A shows, in the Y axis, an increasing rate of the electric field intensity at the boundary position P1 when the electric field intensity in the central portion of the pixel is 100%. This applies to FIGS. 6A, 7A, 8A and 9A. FIG. 5B shows, in the Y axis, the increasing rate of the current density at the boundary position P1 when the current density in the central portion of the pixel is 100%. This applies to FIGS. 6B, 7B, 8B and 9B.

As shown in FIG. 5A, when the bank angle α is 120° or more, the electric field concentration scarcely occurs. In contrast, when the bank angle α is less than 120°, the electric field concentration starts to occur. The electric field concentration decreases as the bank angle α increases. When the bank angle α is an acute angle (less than 90°), the increasing rate of the electric field intensity is 5% or more, which shows remarkable electric field concentration. Thus, the structure pertaining to the present invention is more effective.

As shown in FIG. 5B, the current concentration shows tendency similar to the electric field concentration. In particular, when the bank angle α becomes an acute angle, the increasing rate of the current density is 500% or more, which shows remarkable current concentration. Thus, the structure pertaining to the present invention is more effective.

Note that when the bank angle α is excessively large, a sealing function of the sealing layer 11 and the like disposed over the banks 9 is decreased, which causes moisture to enter the device, for example. When the bank angle α is excessively small, an amount of ink to be applied to form the functional layer is limited such that a desired functional layer cannot be obtained. Accordingly, it is desirable that the bank angle α falls within a range of 90-40°.

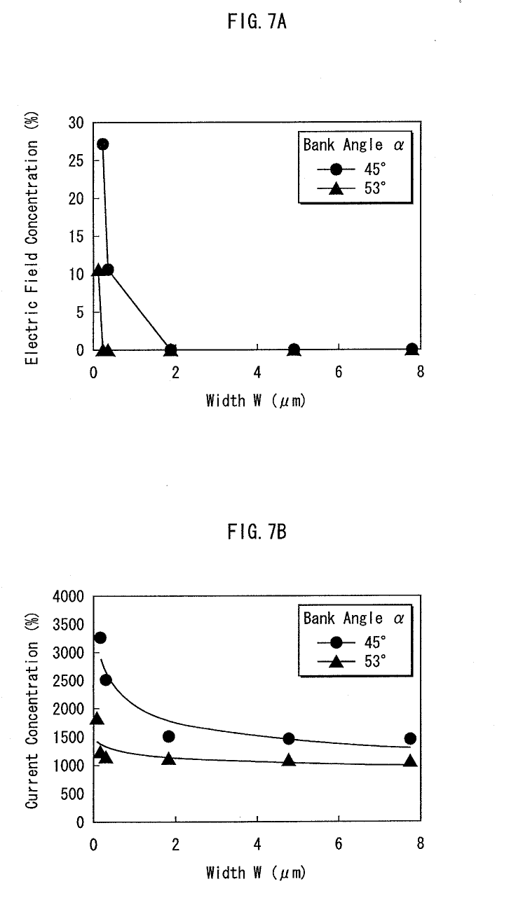

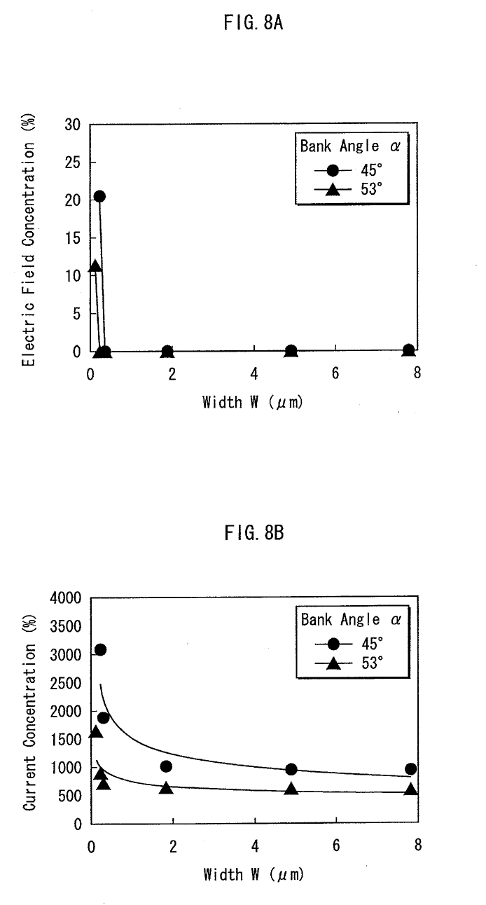

FIGS. 6A, 7A and 8A each show a relation between the width W of the protruding portion 7c and the electric field concentration. FIGS. 6B, 7B and 8B each show the width W of the protruding portion 7c and the current concentration. FIGS. 6A and 6B each show the relation when the height H of the protruding portion 7c is 20 nm. FIGS. 7A and 7B each show the relation when the height H of the protruding portion 7c is 50 nm. FIGS. 8A and 8B each show the relation when the height H of the protruding portion 7c is 90 nm.

As shown in FIGS. 6A and 6B, when the height H of the protruding portion 7c is 20 nm, if the width W of the protruding portion 7c is 2 μm or more, the electric field concentration and the current concentration are remarkably suppressed. If the width W is 5 μm or more, the electric field concentration and the current concentration hardly occur.

As shown in FIGS. 7A and 7B, when the height H of the protruding portion 7c is 50 nm, the electric field concentration and the current concentration hardly occur if the width W of the protruding portion 7c is 2 μm or more. Similarly, as shown in FIGS. 8A and 8B, when the height H of the protruding portion 7c is 90 nm, the electric field concentration and the current concentration hardly occur if the width W of the protruding portion 7c is 2 μm or more.

Accordingly, the width W of the protruding portion 7c is desirably 2 μm or more, and more desirably 5 μm or more. Furthermore, it is desirable that the portion of the light-emitting layer 7 where the thickness is increased is limited to approximately 1% of the whole pixel such that a sensory test shows no variation in the luminance. The width W of the protruding portion 7c is desirably 10% or less of the width of the upper surface 7b of the light-emitting layer 7.

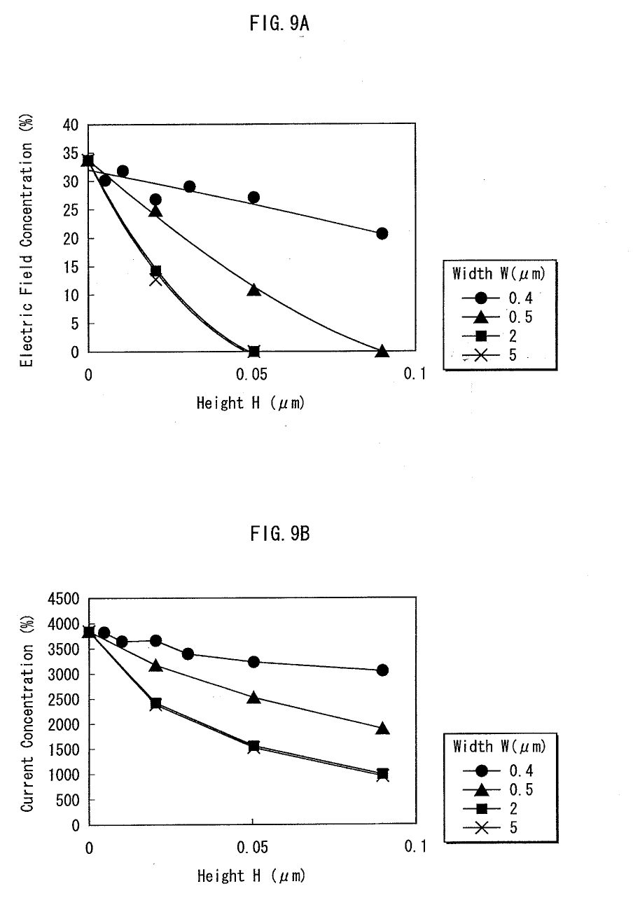

FIG. 9A shows a relation between the height H of the protruding portion 7c and the electric field concentration. FIG. 9B shows a relation between the height H of the protruding portion 7c and the current concentration.

As shown in FIGS. 9A and 9B, when the height H of the protruding portion 7c is 20 nm or more, the electric field concentration and the current concentration start to be remarkably suppressed. Accordingly, the height H of the protruding portion 7c is desirably 20 nm or more.

As above, the description is given of each size of the protruding portion 7c. It is desirable that each size is set as follows in view of the balance of the wholeness of the protruding portion 7c. It is desirable that the width W is 2-20 μm and that the height H is 20 nm or more. In addition, it is especially desirable that the width W is 5-10 μm and that the height H is 50-100 nm.

### [Manufacturing Method of Light-Emitting Device]

A manufacturing method of the light-emitting device in accordance with the embodiment includes a first step of preparing a substrate 1 having, for example, first electrodes 4 disposed thereon, a second step of forming the banks 9 to surround at least part of the first electrodes 4, a third step of forming the light-emitting layer 7 by applying ink including an organic light-emitting material to portions of the light-emitting layer defined by the banks 9, and a fourth step of forming the second electrode 10 on the light-emitting layer 7.

In the first step, first electrodes 4 (material: APC, thickness: 50 nm) are formed in a matrix form or a line form on the glass substrate 1 using a sputtering method. Furthermore, the hole-injection layer 5 is formed on the first electrode 4. Note that the first electrode 4 may be formed using a vapor deposition method, a photolithography method or the like. The forming step of the hole-injection layer 5 is not particularly limited.

In the second step, the banks 9 (material: silicon oxide, height: 1 μm, bank angle α: 45°) is formed using a CVD method to surround part of the hole-injection layer 5. Note that the banks 9 may be formed using, for instance, the photolithography method. In such a case, a resin film may be formed by a coating method or the like on the substrate 1 having the first electrode 4 formed thereon. Light may be radiated on the resin film via a mask to remove desired portions of the resin film.

In the third step, the functional layer including the hole-injection layer 5, the interlayer 6, the light-emitting layer 7 and the electron-injection layer 8 is formed within the portions of the light-emitting layer delimited by the banks 9 using the coating method. According to the coating method, ink containing a material of each layer is applied by using inkjet, dispenser, nozzle coating, spin coating, intaglio printing, anastatic printing or the like, and is dried to form the layers.

More specifically, initially, solution containing PEDOT is coated within the portions delimited by the banks 9 and dried to form a PEDOT layer (thickness: 65 nm) as the hole-injection layer 5. Subsequently, a solution containing 0.8 wt % of triphenylamine (solvent: anisole) is coated and dried to form the interlayer 6 (thickness: 20 nm). Subsequently, solution containing 1.3 wt % of polyfluorene (solvent: cyclohexylbenzene) is coated and dried. Thus, the light-emitting layer 7 (thickness: 85 nm) is formed. In addition, barium is vacuum deposited to form the electron-injection layer 8 (thickness: 5 nm).

In particular, as for the light-emitting layer 7, a dry condition of the coated light-emitting layer 7 is important for making the protruding portion 7c in a desired shape. It is favorable that the light-emitting layer 7 is dried in vacuum, for example, at 30° C., for 20 minutes.

In the fourth step, a second electrode 10 is formed on the electron-injection layer 8 using a facing target sputtering method (material: ITO, thickness: 100 nm). Furthermore, the sealing layer 11 is formed on the second electrode 10. Note that the means for forming the sealing layer 11 is not limited in particular.

### [Modification]

As above, the detailed description is given of the light-emitting device and the display apparatus based on the embodiment. However, the light-emitting device and the display apparatus pertaining to the present invention do not need to be implemented as shown in the above embodiment.

For example, the present invention does not need to have the sloping portion whose upper surface slopes upwardly from the position nearer the center of the pixel than the boundary position P1 towards the lateral surface of the bank to make the light-emitting layer thicker at the boundary position P1 than at the center thereof.

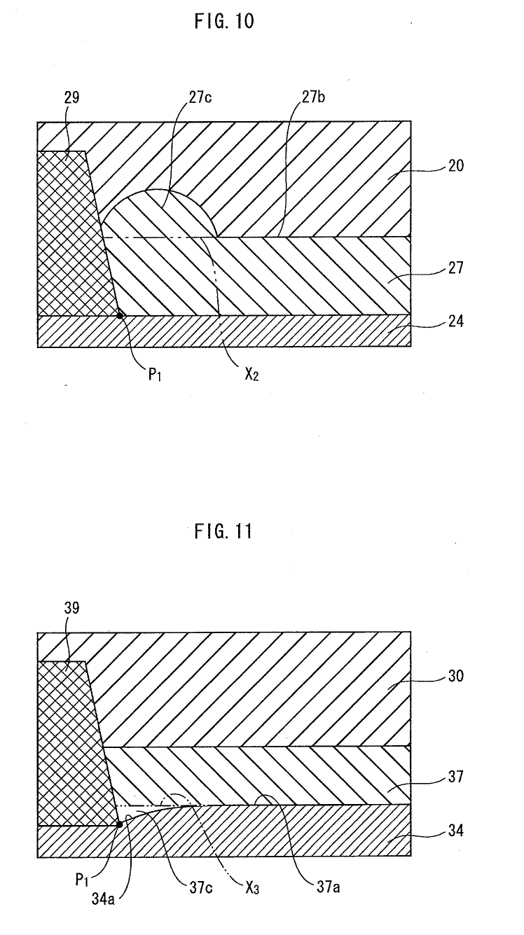

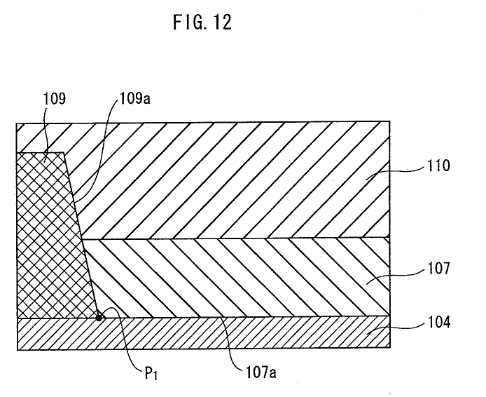

FIG. 10 is a schematic view of the main structure of a light-emitting device pertaining to Modification 1. As shown in FIG. 10, the light-emitting device pertaining to Modification 1 with the following structure is applicable. The light-emitting device has a first electrode 24, a light-emitting layer 27 and a second electrode 20 layered in the stated order. At least the light-emitting layer 27 is delimited by banks 29 to define a pixel. A protruding portion 27c, which is substantially hemispherical in its cross section, is provided on the upper surface 27b of the light-emitting layer 27 (in FIG. 10, a portion above the chain double-dashed line X₂), and a surface of the protruding portion 27c on the upper surface 27b of the light-emitting layer 27 is elevated in a convex form around the boundary position P1. In such a case as well, the distance between the first electrode 24 and the second electrode 20 is long at the boundary position P1, which is effective in suppressing the electric field concentration and the current concentration.

FIG. 11 is a schematic view of the main structure of the light-emitting device pertaining to Modification 2. As shown in FIG. 11, the light-emitting device with the following structure is applicable. The light-emitting device pertaining to Modification 2 has a first electrode 34, a light-emitting layer 37 and a second electrode 30 layered in the stated order. At least the light-emitting layer 37 is delimited by banks 39 to define a pixel. An upper surface 34a of the first electrode 34 slopes downwardly from a position nearer the center of the pixel than the boundary position P1 towards the lateral surface of a corresponding one of the banks 39, which forms the sloping surface. Thus, a protruding portion 37c is provided towards the lower surface 37a of the light-emitting layer 37 (in FIG. 11, portion below the chain double-dashed line X₃). In such a case as well, the distance between the first electrode 34 and the second electrode 30 is long at the boundary position P1, which is effective in suppressing the electric field concentration and the current concentration.

Furthermore, it is possible to combine the protruding portion 7c pertaining to the embodiment, the structure of the protruding portion 27c pertaining to Modification 1 and the structure of the protruding portion 37c pertaining to Modification 2.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

### INDUSTRIAL APPLICABILITY

The present invention is applicable to an organic EL display apparatus designed for use as a flat surface light source, a flat display and the like.

1. A light-emitting device, comprising:
a first electrode;
a second electrode
a light-emitting layer between the first electrode and the second electrode;
banks that delimit the light-emitting layer;
wherein an upper surface of the light-emitting layer has a pair of sloping portions, each of the sloping portions slopes upward toward a lateral surface of one of the banks, the light-emitting layer is thicker about a lower boundary position than at a center of the light-emitting layer, the boundary position corresponds to an intersection of a lower surface of the light-emitting layer and the lateral surface of one of the banks, and
wherein a width of each of the sloping portions is at least approximately 2 μm and at most approximately 10% of a width of the light-emitting layer.

2. The light-emitting device of claim 1, wherein
an upper boundary position is located at an intersection of the upper surface of the light-emitting layer and the lateral surface of one of the banks and displaced from the upper surface of the light-emitting layer at the center by at least approximately 20 nm.

3. The light-emitting device of claim 2, wherein
the width of each of the sloping portions is at least approximately 5 μm and at most approximately 10 μm, and the upper boundary position is displaced from the upper surface of the light-emitting layer at the center by at least approximately 50 nm and at most approximately 100 nm.

4. The light-emitting device of claim 1, wherein
an angle α formed between the lateral surface of one of the banks and a lower surface of the one of the banks is an acute angle.

5. The light-emitting device of claim 1, wherein
the banks surround a periphery of the light-emitting layer.

6. The light-emitting device of claim 1, wherein
the banks are disposed on two opposing sides of the light-emitting layer in one of a row direction and a column direction.

7. The light-emitting device of claim 1, wherein
a lower surface of the one of the banks is in contact with the first electrode, a top surface of the one of the banks is in the second electrode, and the one of the banks slopes from the lower surface to the top surface.

8. A display apparatus having the light-emitting device of claim 1.

9. A light-emitting device, comprising:
a pair of electrodes each generally extending along an axis;
a light-emitting layer generally extending along the axis between the pair of electrodes and including a center portion extending between a pair of end portions;
a pair of banks disposed transverse to the axis and delimiting the light-emitting layer,
wherein each end portion of the pair of end portions of the light-emitting layer has a minimum thickness that is greater than a thickness of the center portion of the light-emitting layer, and
wherein each end portion has a width along the axis of at least approximately 2 μm and at most approximately 10% of a width of the light-emitting layer along the axis.

10. The light-emitting device of claim 9, wherein an upper surface of the light-emitting layer is concave.

11. The light-emitting device of claim 10, wherein a lower surface of the light-emitting layer generally extends parallel to the axis.

12. The light-emitting device of claim 9, wherein each bank of the pair of banks has a lateral surface that delimits the light-emitting layer, and an upper surface of each en portion obtusely intersects the lateral surface of one of the pair of banks.

13. The light-emitting device of claim 12, wherein a slope of the upper surface of each end portion rises at least approximately 20 nm.

14. The light-emitting device of claim 13, wherein the width of each end portion is at least approximately 5 μm and at most approximately 10 μm along the axis, and the slope of each end portion rises at least approximately 50 nm and at most approximately 100 nm.

15. The light-emitting device of claim 9, wherein each bank of the pair of banks has a lateral surface that delimits the light-emitting layer, and the lateral surface of each bank obliquely intersects the axis.

16. The light-emitting device of claim 15, wherein an upper surface of each end portion obtusely intersects the lateral surface of one of the pair of banks.

17. The light-emitting device of claim 16, wherein a slope of the upper surface of each end portion rises at least approximately 20 nm.

18. The light-emitting device of claim 17, wherein the width of each end portion is at least approximately 5 μm and at most approximately 10 μm along the axis, and the slope of each end portion rises at least approximately 50 nm and at most approximately 100 nm.

19. The light-emitting device of claim 9, wherein each bank of the pair of banks has a lateral surface that delimits the light-emitting layer, and a lower surface of each end portion acutely intersects the lateral surface of one of the pair of banks.

20. A display apparatus having the light-emitting device of claim 9.
